(19) United States
(12) Patent Application Publication
(10) Pub. No.: US 2025/0185336 A1
(43) Pub. Date: Jun. 5, 2025

(54) RESISTANCE REDUCTION BY FORMING CONDUCTIVE VIA ON BACK SIDE OF SOURCE/DRAIN CONTACTS

(71) Applicant: Taiwan Semiconductor Manufacturing Company, Ltd., Hsin-Chu (TW)

(72) Inventors: Shih-Chieh Wu, Hsinchu (TW); Chen-Ming Lee, Taoyuan County (TW); Po-Yu Huang, Hsinchu (TW); I-Wen Wu, Hsinchu City (TW); Mei-Yun Wang, Hsin-Chu (TW)

(21) Appl. No.: 18/528,465

(22) Filed: Dec. 4, 2023

(51) Int. Cl. H01L 29/417; H01L 29/06; H01L 29/40; H01L 29/423; H01L 29/775; H01L 29/786

(52) U.S. Cl. CPC H10D 64/254; H10D 30/43; H10D 30/6735; H10D 30/6757; H10D 62/121; H10D 64/01

(57) ABSTRACT

A semiconductor device includes a plurality of source/drain regions. The semiconductor device includes a plurality of source/drain contacts disposed over a front side of the plurality of source/drain regions, respectively. The plurality of the source/drain contacts are electrically coupled to the plurality of source/drain regions. The semiconductor device includes a plurality of conductive vias disposed over a back side of the source/drain contacts, respectively. The back side is opposite the front side. The plurality of the conductive vias are electrically coupled to the plurality of source/drain contacts.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

As the scaling down process continues, certain challenges may arise. For example, conductive vias may be formed to provide electrical connectivity to the components of an IC. However, when certain types of conductive vias are formed on an epitaxially-grown semiconductor regions, it may increase the parasitic resistance, which is undesirable. Such a problem may be exacerbated as the dimensions of the conductive via continues to shrink as IC fabrication advances to newer technology nodes.

Therefore, although semiconductor devices and their methods of fabrication have been generally adequate for their intended purposes, they have not been entirely satisfactory in every aspect.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion. It is also emphasized that the drawings appended illustrate only typical embodiments of this invention and are therefore not to be considered limiting in scope, for the invention may apply equally well to other embodiments.

FIG. 1A illustrates a three-dimensional perspective view of a FinFET device.

FIG. 1B illustrates a top view of a FinFET device.

FIG. 1C illustrates a three-dimensional perspective view of a multi-channel gate-all-around (GAA) device.

FIGS. 2-7 illustrate a series of Y-cut cross-sectional views of a semiconductor device at various stages of fabrication according to embodiments of the present disclosure.

FIGS. 8-9 illustrate a series of Y-cut cross-sectional views of a semiconductor device at various stages of fabrication according to embodiments of the present disclosure.

FIG. 10 is a block diagram of a manufacturing system according to various aspects of the present disclosure.

FIG. 11 is a flowchart illustrating a method of fabricating a semiconductor device according to various aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Still further, when a number or a range of numbers is described with “about,” “approximate,” and the like, the term is intended to encompass numbers that are within a reasonable range including the number described, such as within +/−10% of the number described or other values as understood by person skilled in the art. For example, the term “about 5 nm” encompasses the dimension range from 4.5 nm to 5.5 nm.

The present disclosure is generally related to a unique fabrication process flow to form back side vias directly on source/drain contacts. In more detail, conductive vias may be formed on a back side of an Integrated Circuit (IC) device. If such a back side conductive via is formed on an epitaxially-grown semiconductor region (e.g., a source/drain region of a transistor), it could lead to a higher resistance, which is undesirable, since it could adversely affect device performance such as speed. Therefore, the present disclosure performs various fabrication processes to ensure that the back side conductive via is formed on a source/drain contact instead. Doing so will reduce the resistance of the IC device and therefore improve IC device performance.

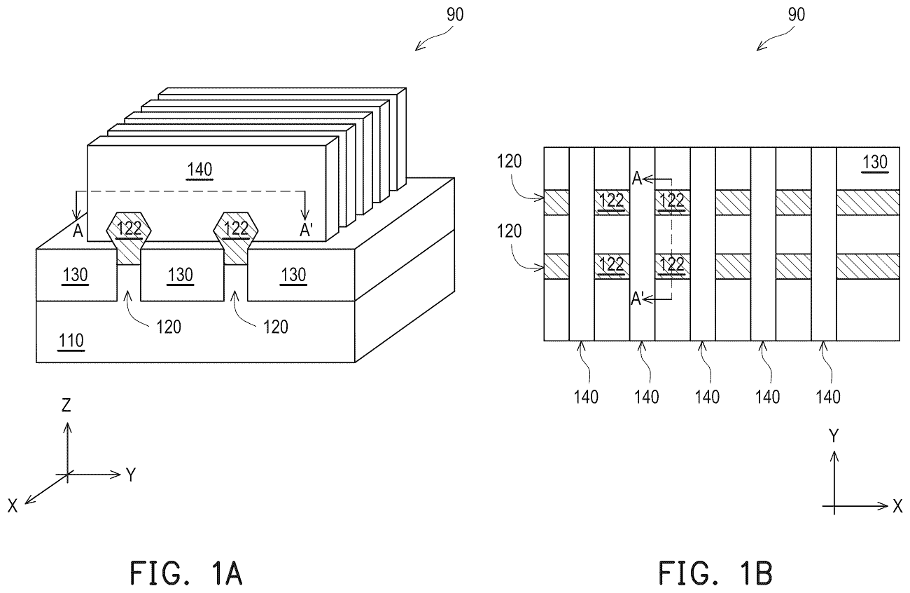

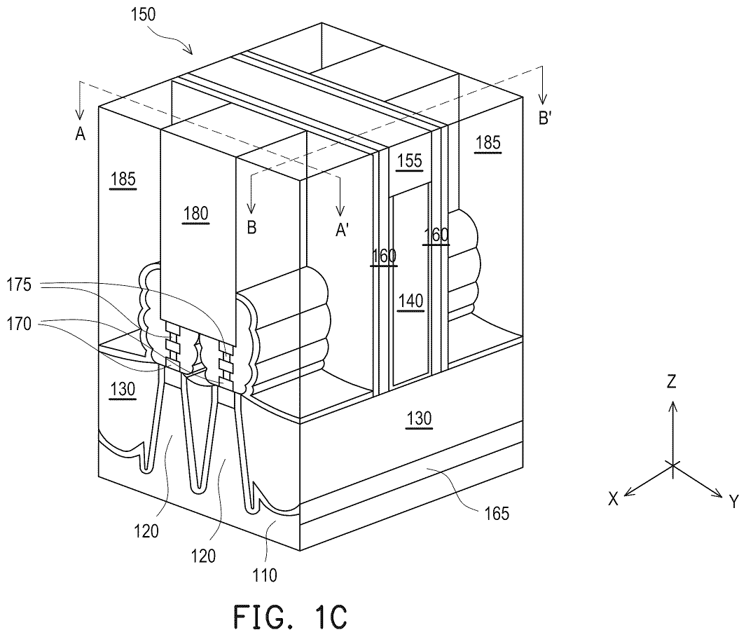

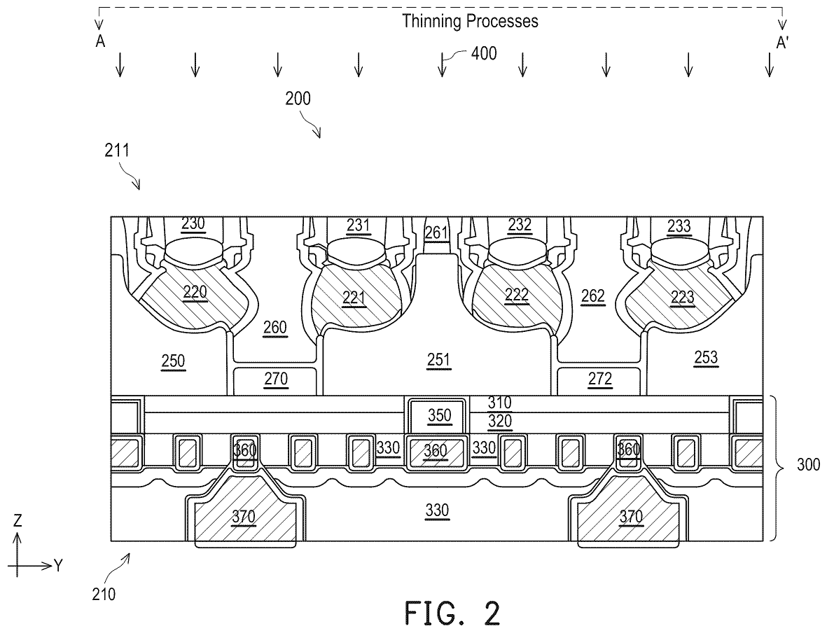

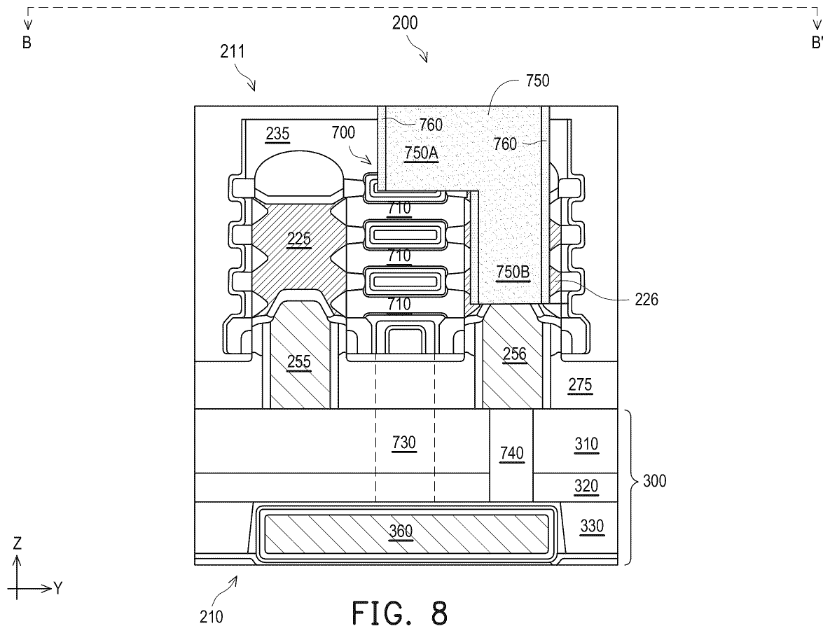

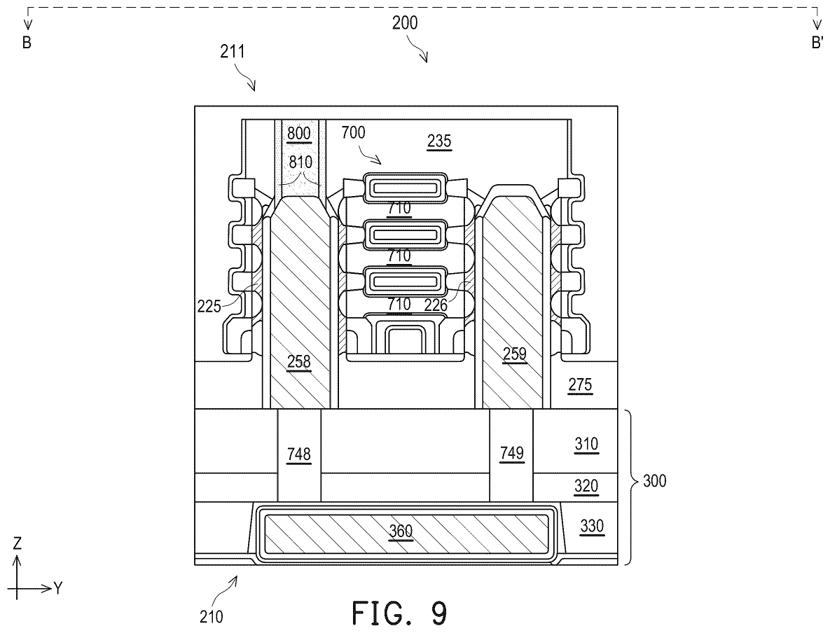

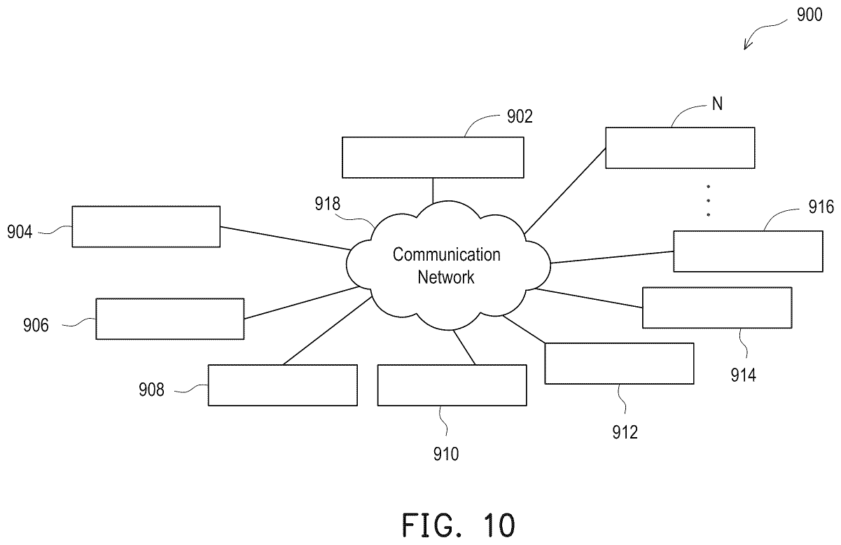

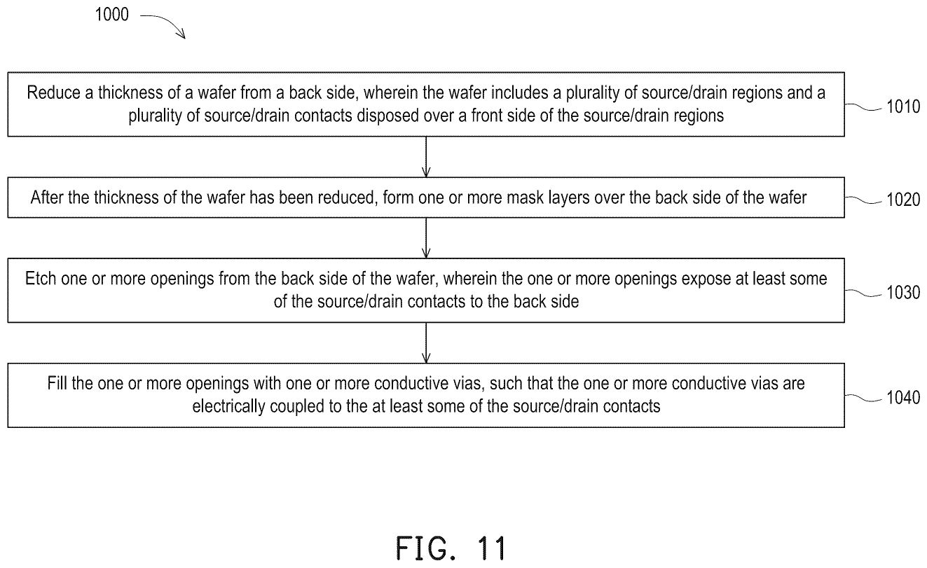

The various aspects of the present disclosure will now be discussed below with reference to FIGS. 1A, 1B, 1C, 2-11. In more detail, FIGS. 1A-1B illustrate an example FinFET device, and FIG. 1C illustrates an example GAA device. FIGS. 2-7 illustrate Y-cut cross-sectional side views of an IC device at various stages of fabrication according to embodiments of the present disclosure. FIGS. 8-9 illustrate X-cut cross-sectional side views of the IC device at various stages of fabrication according to embodiments of the present disclosure. FIG. 10 illustrates a semiconductor fabrication system that may be used to fabricate the IC device of the present disclosure. FIG. 11 illustrates a flowchart of a method of fabricating the IC device of the present disclosure.

Referring now to FIGS. 1A and 1B, a three-dimensional perspective view and a top view of a portion of an Integrated Circuit (IC) device 90 are illustrated, respectively. The IC device 90 is implemented using field-effect transistors (FETs) such as three-dimensional fin-line FETs (FinFETs). FinFET devices have semiconductor fin structures that protrude vertically out of a substrate. The fin structures are active regions, from which source/drain region(s) and/or channel regions are formed. Source/drain region(s) may refer to a source or a drain, individually or collectively dependent upon the context. A source/drain region may also refer to a region that provides a source and/or drain for multiple devices. The gate structures partially wrap around the fin structures. In recent years, FinFET devices have gained popularity due to their enhanced performance compared to conventional planar transistors.

As shown in FIG. 1A, the IC device 90 includes a substrate 110. The substrate 110 may comprise an elementary (single element) semiconductor, such as silicon, germanium, and/or other suitable materials; a compound semiconductor, such as silicon carbide, gallium arsenic, gallium phosphide, indium phosphide, indium arsenide, indium antimonide, and/or other suitable materials; an alloy semiconductor such as SiGe, GaAsP, AlInAs, AlGaAs, GaInAs, GaInP, GaInAsP, and/or other suitable materials. The substrate 110 may be a single-layer material having a uniform composition. Alternatively, the substrate 110 may include multiple material layers having similar or different compositions suitable for IC device manufacturing. In one example, the substrate 110 may be a silicon-on-insulator (SOI) substrate having a semiconductor silicon layer formed on a silicon oxide layer. In another example, the substrate 110 may include a conductive layer, a semiconductor layer, a dielectric layer, other layers, or combinations thereof. Various doped regions, such as source/drain regions, may be formed in or on the substrate 110. The doped regions may be doped with n-type dopants, such as phosphorus or arsenic, and/or p-type dopants, such as boron, depending on design requirements. The doped regions may be formed directly on the substrate 110, in a p-well structure, in an n-well structure, in a dual-well structure, or using a raised structure. Doped regions may be formed by implantation of dopant atoms, in-situ doped epitaxial growth, and/or other suitable techniques.

Three-dimensional active regions 120 are formed on the substrate 110. The active regions 120 may include elongated fin-like structures that protrude upwardly out of the substrate 110. As such, the active regions 120 may be interchangeably referred to as fin structures 120 or fins 120 hereinafter. The fin structures 120 may be fabricated using suitable processes including photolithography and etch processes. The photolithography process may include forming a photoresist layer overlying the substrate 110, exposing the photoresist to a pattern, performing post-exposure bake processes, and developing the photoresist to form a masking element (not shown) including the resist. The masking element is then used for etching recesses into the substrate 110, leaving the fin structures 120 on the substrate 110. The etching process may include dry etching, wet etching, reactive ion etching (RIE), and/or other suitable processes. In some embodiments, the fin structure 120 may be formed by double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. As an example, a layer may be formed over a substrate and patterned using a photolithography process. Spacers are formed alongside the patterned layer using a self-aligned process. The layer is then removed, and the remaining spacers, or mandrels, may then be used to pattern the fin structures 120.

The IC device 90 also includes source/drain components 122 formed over the fin structures 120. The source/drain components 122 (also referred to source/drain regions) may refer to a source or a drain of a transistor, individually or collectively, dependent upon the context. The source/drain components 122 may include epi-layers that are epitaxially grown on the fin structures 120. The IC device 90 further includes isolation structures 130 formed over the substrate 110. The isolation structures 130 electrically separate various components of the IC device 90. The isolation structures 130 may include silicon oxide, silicon nitride, silicon oxynitride, fluoride-doped silicate glass (FSG), a low-k dielectric material, and/or other suitable materials. In some embodiments, the isolation structures 130 may include shallow trench isolation (STI) features. In one embodiment, the isolation structures 130 are formed by etching trenches in the substrate 110 during the formation of the fin structures 120. The trenches may then be filled with an isolating material described above, followed by a chemical mechanical planarization (CMP) process. Other isolation structure such as field oxide, local oxidation of silicon (LOCOS), and/or other suitable structures may also be implemented as the isolation structures 130. Alternatively, the isolation structures 130 may include a multi-layer structure, for example, having one or more thermal oxide liner layers.

The IC device 90 also includes gate structures 140 formed over and engaging the fin structures 120 on three sides in a channel region of each fin 120. In other words, the gate structures 140 each wrap around a plurality of fin structures 120. The gate structures 140 may be dummy gate structures (e.g., containing an oxide gate dielectric and a polysilicon gate electrode), or they may be High-k metal gate (HKMG) structures that contain a high-k gate dielectric and a metal gate electrode, where the HKMG structures are formed by replacing the dummy gate structures. Though not depicted herein, the gate structure 140 may include additional material layers, such as an interfacial layer over the fin structures 120, a capping layer, other suitable layers, or combinations thereof.

Referring to FIGS. 1A-1B, multiple fin structures 120 are each oriented lengthwise along the X-direction, and multiple gate structures 140 are each oriented lengthwise along the Y-direction, i.e., generally perpendicular to the fin structures 120. In many embodiments, the IC device 90 includes additional features such as gate spacers disposed along sidewalls of the gate structures 140, hard mask layer(s) disposed over the gate structures 140, and numerous other features.

FIG. 1C illustrates a three-dimensional perspective view of an example multi-channel gate-all-around (GAA) device 150. GAA devices have multiple elongated nano-structure channels that may be implemented as nano-tubes, nano-sheets, or nano-wires. For reasons of consistency and clarity, similar components in FIG. 1C and FIGS. 1A-1B will be labeled the same. For example, active regions such as fin structures 120 rise vertically upwards out of the substrate 110 in the Z-direction. The isolation structures 130 provide electrical separation between the fin structures 120. The gate structure 140 is located over the fin structures 120 and over the isolation structures 130. A layer 155 is located over the gate structure 140, and gate spacer structures 160 are located on sidewalls of the gate structure 140. A capping layer 165 is formed over the fin structures 120 to protect the fin structures 120 from oxidation during the forming of the isolation structures 130.

A plurality of nano-structures 170 is disposed over each of the fin structures 120. The nano-structures 170 may include nano-sheets, nano-tubes, or nano-wires, or some other type of nano-structure that extends horizontally in the X-direction. Portions of the nano-structures 170 under the gate structure 140 may serve as the channels of the GAA device 150. Dielectric inner spacers 175 may be disposed between the nano-structures 170. In addition, although not illustrated for reasons of simplicity, each stack of the nano-structures 170 may be wrapped around circumferentially by a gate dielectric as well as a gate electrode. In the illustrated embodiment, the portions of the nano-structures 170 outside the gate structure 140 may serve as the source/drain features of the GAA device 150. However, in some embodiments, continuous source/drain features may be epitaxially grown over portions of the fin structures 120 outside of the gate structure 140. Regardless, conductive source/drain contacts 180 may be formed over the source/drain features to provide electrical connectivity thereto. An interlayer dielectric (ILD) 185 is formed over the isolation structures 130 and around the gate structure 140 and the source/drain contacts 180. The ILD 185 may be referred to as an ILD0 layer. In some embodiments, the ILD 185 may include silicon oxide, silicon nitride, or a low-k dielectric material.

The FinFET devices of FIGS. 1A-1B and the GAA devices of FIG. 1C may be utilized to implement electrical circuitries having various functionalities, such as memory devices (e.g., static random access memory (SRAM) devices), logic circuitries, input/output (I/O) devices, application specific integrated circuit (ASIC) devices, radio frequency (RF) circuitries, drivers, micro-controllers, central processing units (CPUs), image sensors, etc., as non-limiting examples.

FIGS. 2-7 illustrate diagrammatic fragmentary cross-sectional views of portions of an IC device 200 at various stages of fabrication according to various embodiments of the present disclosure. In more detail, FIGS. 2-7 illustrate the cross-sectional views along a Y-Z plane, which may be taken alone a cutline A-A′ shown in FIGS. 1A-1C. As such, FIGS. 2-7 may be referred to as Y-cuts or Y-cut cross-sectional views.

Referring now to FIG. 2, the IC device 200 has a side 210 and a side 211 that is opposite the first side. In the illustrated embodiments, the side 210 is a front side, and it may be interchangeably referred to as a front side 210 hereinafter. The side 211 is a back side, and it may be interchangeably referred to as a back side 211 hereinafter.

The IC device 200 may include a plurality of transistors, such as the FinFET transistors discussed above with reference to FIGS. 1A and 1B in some embodiments, or the gate-all-around (GAA) transistors discussed above with reference to FIG. 1C in some other embodiments. In the cross-sectional side view of FIG. 2, a plurality of source/drain regions 220, 221, 222, and 223 are illustrated for various transistors. The source/drain regions 220-223 may be embodiments of the source/drain components 122 discussed above with reference to FIGS. 1A-1C. Again, each of the source/drain regions 220-223 may refer to a source or a drain of a transistor, individually or collectively, dependent upon the context. The source/drain regions 220-223 may include epi-layers that are epitaxially grown on semiconductor materials 230, 231, 232, and 233, respectively, which may include silicon. In some embodiments, the semiconductor materials 230-233 may include portions of a semiconductor substrate, such as active regions. For example, the active regions may include portions of the fin structure 120 discussed above with reference to FIGS. 1A-1C.

Conductive contacts may be formed over the front side 210 of the source/drain regions 220-223 to provide electrical connectivity to the source/drain regions 220-223. For example, a plurality of source/drain contacts 250, 251, and 252 may be formed. The source/drain contact 250 is formed over the front side 210 of the source/drain region 220, the source/drain contact 251 is formed over the front side 210 of the source/drain regions 221 and 222, and the source/drain contact 253 is formed over the front side 210 of the source/drain region 223. The source/drain contacts 250, 251, and 253 may be formed by etching openings that expose the source/drain regions 220-223 to the front side 210, and thereafter filling the etched openings with one or more conductive materials, such as cobalt or tungsten.

The source/drain regions 220 and 221 are electrically and physically separated from one another by a shallow trench isolation (STI) structure 260, the source/drain regions 221 and 222 are electrically and physically separated from one another by an STI structure 261, and the source/drain regions 222 and 223 are electrically and physically separated from one another by an STI structure 262. Note that the STI 261 is formed over the back side 211 of the source/drain contact 251. The source/drain contacts 250 and 251 are electrically and physically separated from one another by the STI structure 260 and also by an interlayer dielectric (ILD) layer 270. The source/drain contacts 251 and 253 are electrically and physically separated from one another by the STI structure 262 and also by an ILD layer 272.

The STI structures 260-262 and the ILD layers 270-272 may include silicon oxide or another suitable type of dielectric material. In some embodiments, the STI structures 260-262 and the ILD layers 270-272 have different material compositions. In other embodiments, the STI structures 260-262 and the ILD layers 270-272 may contain the same type of dielectric materials. It is understood that the formation of the source/drain contacts 250, 251, and 253 may involve etching openings at least partially through the ILD layers 270-272 and/or the STI structures 260-262, such that the etched openings expose the source/drain regions 220-223 to the front side 210. These etched openings are then filled with conductive materials to form the source/drain contacts 250, 251, and 253.

Although not directly visible in the Y-cut cross-sectional side view of FIG. 2, it is understood that the transistors of the IC device 200 also includes gate structures. In some embodiments, the gate structures may be implemented as high-k metal gate (HKMG) structures. For example, each HKMG structure may partially wrap around one of the active regions (e.g., wrapping around a fin structure). As discussed above, the HKMG structures are formed by replacing dummy gate structures, and they may each include a high-k gate dielectric and a metal-containing gate electrode. Example materials of the high-k gate dielectric include hafnium oxide, zirconium oxide, aluminum oxide, hafnium dioxide-alumina alloy, hafnium silicon oxide, hafnium silicon oxynitride, hafnium tantalum oxide, hafnium titanium oxide, hafnium zirconium oxide, or combinations thereof. The metal-containing gate electrode may include one or more work function metal layers and one or more fill metal layers. The work function metal layers may be configured to tune a work function of the respective transistor. Example materials for the work function metal layers may include titanium nitride (TiN), Titanium aluminide (TiAl), tantalum nitride (TaN), titanium carbide (TiC), tantalum carbide (TaC), tungsten carbide (WC), titanium aluminum nitride (TiAlN), zirconium aluminide (ZrAl), tungsten aluminide (WAl), tantalum aluminide (TaAl), hafnium aluminide (HfAl), or combinations thereof. The fill metal layer may serve as a main conductive portion of the gate electrode layer. The gate structures may include additional material layers, such as an interfacial layer between the active region and the gate dielectric layer.

Still referring to FIG. 2, an interconnect structure 300 is formed on the front side 210 of the IC device 200 to provide electrical connectivity to the various components of the IC device 200. In more detail, the interconnect structure 300 includes a plurality of electrically insulating layers, such as an etching-stop layer 310, an ILD layer 320, and a dielectric layer 330. Each of these layers 310, 320, or 330 may include a suitable type of electrically insulating material, for example, silicon oxide, silicon nitride, silicon oxynitride, silicon carbide, fluoride-doped silicate glass (FSG), a low-k dielectric material, or combinations thereof.

The interconnect structure 300 further includes a plurality of electrically conductive components. For example, The interconnect structure 300 may include a conductive via 350 that is embedded in, and that vertically extends through, the etching-stop layer 310 and the ILD layer 320. The via 350 is also electrically coupled to the front side 210 of the source/drain contact 251, and as such, the via 350 may also be referred to as a source/drain via 350. The interconnect structure 300 also includes a plurality of metal lines, such as the metal lines 360 and the metal lines 370. The metal lines 360 are metal lines of a metal-0 (also referred to as M0) metal layer, and the metal lines 370 are metal lines of a metal-1 (also referred to as M1) metal layer. The metal lines 360 and the metal lines 370 may be embedded in the dielectric layer 330, which provides electrical isolation for the various metal lines 360 and 370 from their adjacent metal lines. Note that some of the metal lines 360 and some of the metal lines 370 are electrically coupled together.

It is understood that the interconnect structure 300 is formed as a part of the IC device 200 after the source/drain contacts 250, 251, and 253 have been formed. In other words, the interconnect structure 300 may be formed using a layer-by-layer approach over the front side 210 of the IC device 200, such that the components (e.g., source/drain vias 350) of the interconnect structure 300 provide electrical connectivity (from the front side 210) to the source/drain regions 220-223 at least in part through the source/drain contacts 250, 251, and 253.

Still referring to FIG. 2, one or more thinning processes 400 may be performed on the IC device 200 from the back side 211. As such, the one or more thinning processes 400 may also be referred to as a back side thin down process. In some embodiments, the one or more thinning processes 400 may include one or more chemical etching processes, and/or one or more mechanical grinding processes, to reduce a thickness of the IC device 200 by partially removing its materials. For example, the chemical etching processes and/or the mechanical grinding processes may etch or grind away a portion of a substrate of the IC device 200, which may be a silicon substrate in some embodiments.

It is understood that the thinning processes 400 may be performed while the front side 210 of the IC device 200 is attached to a supporting substrate, which may provide mechanical strength and support to the IC device 200 while the thinning processes 400 are performed. The supporting substrate may be removed from the IC device 200 after the completion of the thinning processes 400. For reasons of simplicity, such a supporting substrate is not illustrated in FIG. 2.

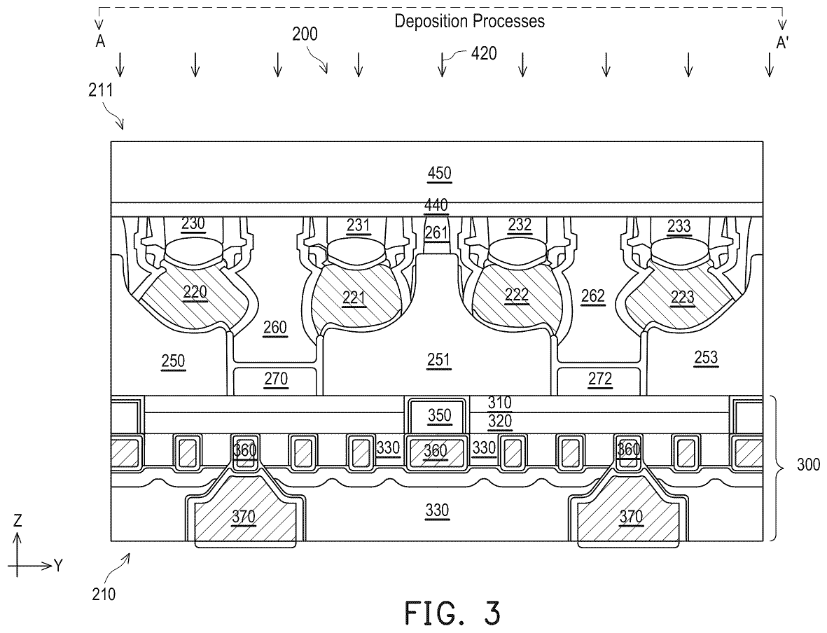

Referring now to FIG. 3, a plurality of deposition processes 420 are performed to the IC device 200 to form one or more mask layers over the back side 211 of the IC device 200. For example, a first deposition process of the deposition processes 420 may be performed to deposit a mask layer 440 over the back side 211 of the IC device 200, which has already been thinned down at this stage of fabrication. Thereafter, a second deposition process of the deposition processes 420 may be performed to deposit a mask layer 450 over the back side 211 of the mask layer 440. In some embodiments, the first deposition process and/or the second deposition process may include a chemical vapor deposition (CVD) process, a physical vapor deposition (PVD) process, an atomic layer deposition (ALD) process, or combination thereof. The deposited materials of the mask layer 440 and the mask layer 450 may be different type of materials in some embodiments, or they may be a same type of material in other embodiment. In some embodiments, the mask layer 440 is deposited to contain silicon nitride as its material, and the mask layer 450 is deposited to contain silicon oxide as its material. The mask layer 440 and the mask layer 450 may also be deposited such that the mask layer 450 is thicker than the mask layer 440. In some embodiments, a thickness of the mask layer 440 is in a range between about 5 nanometers (nm) and about 15 nm, and a thickness of the mask layer 450 is in a range between about 15 nm and about 45 nm.

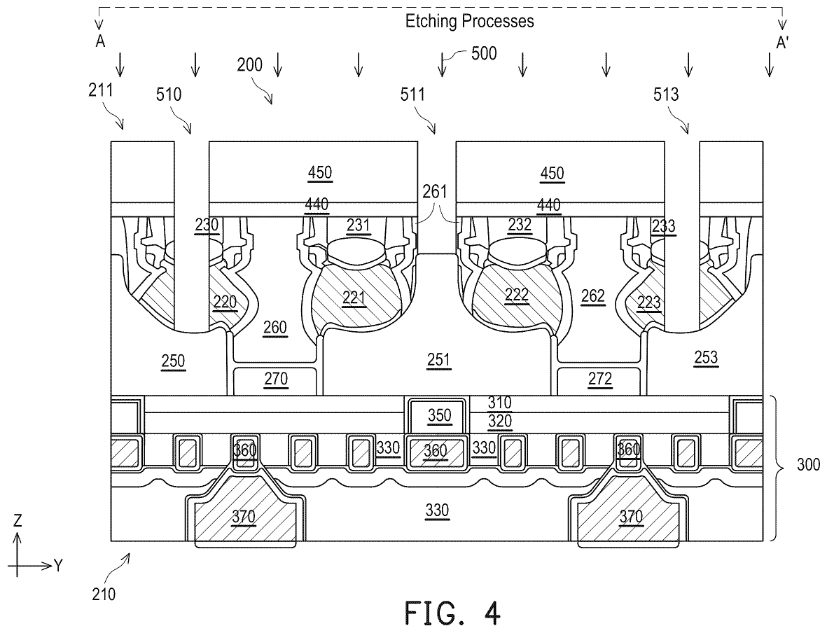

Referring now to FIG. 4, one or more etching processes 500 are performed to the IC device 200 to form a plurality of openings in the IC device 200. For example, the one or more etching processes 500 may etch openings 510, 511, and 513 in the IC device 200. The opening 510 is etched to extend vertically (in the Z-direction) through the mask layers 450 and 440, as well as through the semiconductor material 230 and the source/drain region 220, such that the source/drain contact 250 is exposed to the back side 211. The opening 511 is etched to extend vertically (in the Z-direction) through the mask layers 450 and 440, as well as the STI 261, such that the source/drain contact 251 is exposed to the back side 211. The opening 513 is etched to extend vertically (in the Z-direction) through the mask layers 450 and 440, as well as the semiconductor material 233 and the source/drain region 223, such that the source/drain contact 253 is exposed to the back side 211.

In some embodiments, the one or more etching processes 500 may include a same etching process to etch all of the openings 510, 511, and 513 at the same time. Such an etching process may be either a wet etching process or a dry etching process. Since different types of materials will be etched (e.g., a silicon material for the openings 510 and 513, compared to a dielectric material (e.g., silicon oxide) for the opening 511), the etching process may be tuned with an etching selectivity between these materials. For example, the etching rates may be configured to be greater for the silicon material and the dielectric material than other materials (e.g., metal materials, or other types of dielectric materials) of the IC device 200. In this manner, the silicon material may be removed in the formation of the openings 510 and 513, and the dielectric material (e.g., silicon oxide) may be removed in the formation of the opening 511, without substantially affecting the rest of the IC device 200.

In other embodiments, two different etching processes may be performed as a part of the one or more etching processes 500. For example, a first etching process may be performed to etch the openings 510 and 513, while the source/drain contact 251 (and the STI structure 261 disposed thereover) remain unetched. Thereafter, a second etching process may be performed to etch the opening 511, while the openings 510 and 513 are protected from being further etched by the second etching process. This could be achieved by either tuning the etching selectivity between the silicon materials 230 and the STI structure 261 in the second etching process, or by protecting the openings 510 and 513 with a protective mask that can be removed later. Of course, the sequence in which the openings 510, 511, and 513 are etched is not important. In other words, it is possible to etch the opening 511 through a first etching process and the openings 510 and 513 through a second etching process later.

Regardless of how the one or more etching processes 500 may be implemented, the end result is that the opening 510 exposes a back-side-facing surface of the source/drain contact 250, the opening 511 exposes a back-side-facing surface of the source/drain contact 251, and that the opening 513 exposes a back-side-facing surface of the source/drain contact 253.

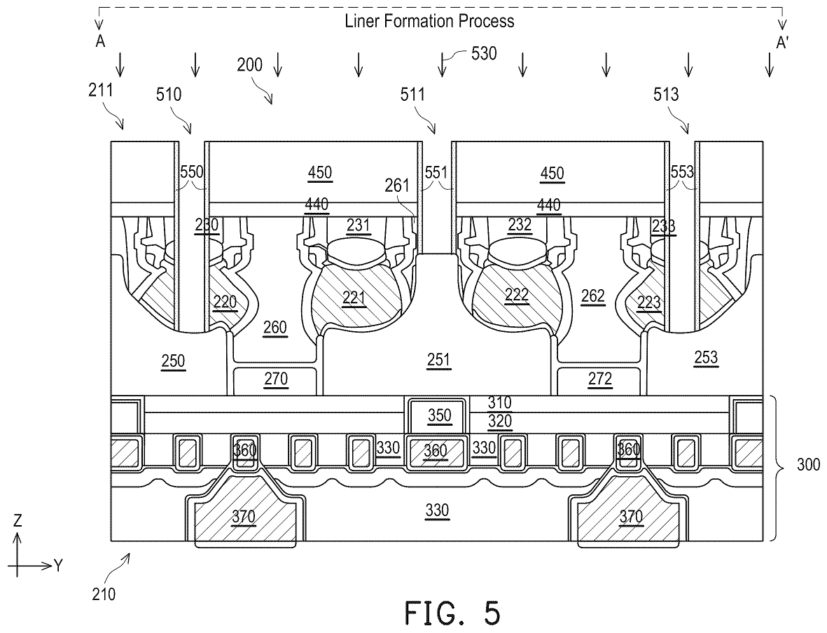

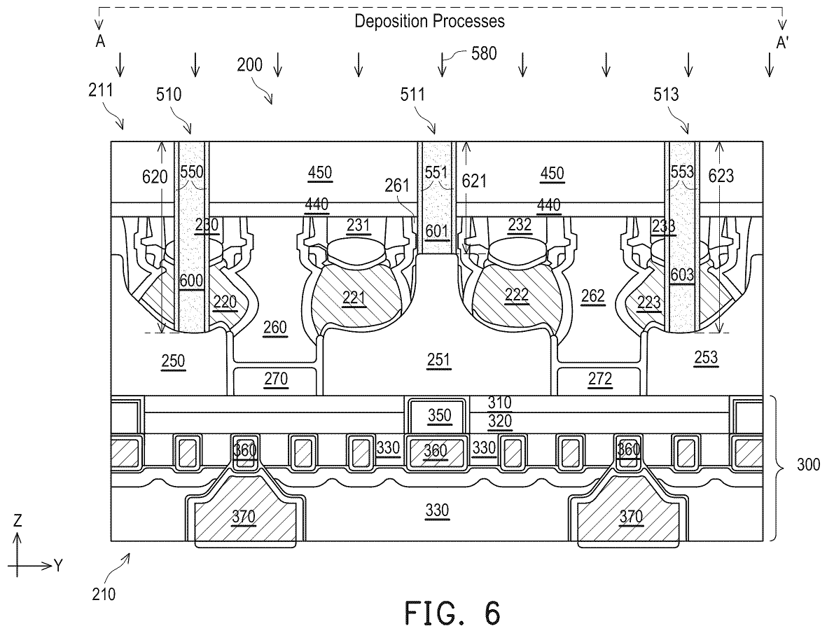

Referring now to FIG. 5, a liner formation process 530 is performed to form liners 550 in the opening 510, liners 551 in the opening 511, and liners 553 in the opening 513. For example, the liner formation process 530 may include a deposition process, such as a CVD process, a PVD process, or an ALD process, to deposit a liner layer on the back side 211 of the IC device 200. Such a liner layer is formed on the surface of the mask layer 450 and partially fills the openings 510, 511, and 513, including on the sidewalls and the bottom surfaces of the opening 510, 511, and 513. In some embodiments, the deposited liner layer includes a dielectric material, for example, silicon nitride. In some embodiments, the deposited liner layer may have a thickness in a range between about 2 nm and about 3 nm.

Thereafter, one or more etching processes may be performed as a part of the liner formation process 530. Such etching processes are configured to have a sufficiently high etching selectivity between the deposited liner layer and the other components (e.g., silicon, silicon oxide, or metal) of the IC device 200. In other words, the material of the liner layer may be etched away at a substantially faster rate than the other components of the IC device 200. As the etching is applied mostly in a downward direction (e.g., toward the front side 210) vertically, the portions of the liner layer on the sidewalls of the openings 510, 511, and 513 remain substantially intact, while the rest of the liner layer is removed. For example, the portion of the liner layer formed on the surface of the mask layer 450 is removed, as is the portion of the liner layer formed on the surface of the source/drain contacts 250, 251, and 253 exposed by the opening 510, 511, and 513, respectively.

As a result of the liner formation process 530, the liners 550, 551, and 553 are formed on the sidewalls of the openings 510, 511, and 513, respectively, while the openings 510, 511, and 513 still leave portions of the source/drain contacts 250, 251, and 253 exposed, respectively. It is understood that the liners 550, 551, and 553 help to prevent the subsequently-formed vias in the openings 510, 511, and 513 from electrically shorting into other components (e.g., gate structures) of the IC device 200.

Referring now to FIG. 6, one or more deposition processes 580 are performed to the IC device 200 to deposit one or more conductive materials in the openings 510, 511, and 513. In some embodiments, the one or more deposition processes 580 include CVD processes, PVD processes, ALD processes, or combinations thereof. In some embodiments, the deposited conductive materials may include a single type of metal material, such as tungsten. In other embodiments, the deposited conductive materials may contain different metallic atomic elements, such as a metal compound or a metal alloy. It is understood that the deposited conductive materials by the deposition processes 580 may be the same type of materials as the source/drain contacts 250, 251, and 253 in some embodiments, or they may be different types of materials in other embodiments.

One or more planarization processes may also be performed following the deposition processes 580 to remove excess portions of the deposited conductive materials outside the openings 510, 511, and 513, and also to planarize the exposed surfaces (e.g., exposed to the back side 211) of the deposited conductive materials in the openings 510, 511, and 513 with the surface of the mask layer 450. As a result, conductive vias 600, 601, and 603 are formed in the openings 510, 511, and 513, respectively. As discussed above, the liners 550, 551, and 553 are disposed on opposite sides of the conductive vias 600, 601, and 603, respectively, and they serve to mitigate the risk of undesirable electrical shorting between the conductive vias 600, 601, and 603 with other components of the IC device 200, such as gate structures.

Note that the conductive vias 600 and 603 are formed with deeper depths than the conductive via 601. For example, the conductive vias 600 and 603 are formed with depths 620 and 623, respectively, whereas the conductive via 601 is formed with a depth 621. The depths 620, 621, and 623 are each measured in the Z-direction vertically, and the depths 620 and 623 are substantially greater than the depth 621. Such a difference in the values of the depths 621 and 620/623 is due to the fact that the conductive via 601 is formed over an uppermost protrusion of the source/drain contact 251 (e.g., protruding in a vertical Z-direction toward the back side 211), whereas the conductive vias 600/603 are each formed over a different part of the source/drain contacts 250/253 that does not protrude toward the back side 211 as much. In some embodiments, the depth 620 is in a range between about 90 nm and about 120 nm, and the depth 621 is in a range between about 50 nm and about 80 nm. In some embodiments, a ratio of the depth 620 and the depth 621 is in a range between about nm and about 1.125:1 and about 2.4.

As an inherent result of the unique fabrication process flow performed herein, a unique physical characteristic of the IC device 200 is that the conductive vias 600, 601, and 603 are formed to be in direct physical contact with the source/drain contacts 250, 251, and 253, respectively, where the conductive vias 600, 601, and 603 are formed over the back side 211 of the source/drain contacts 250, 251, and 253. The conductive vias 600, 601, and 603 may be used to facilitate electrical routing from the back side 211 of the IC device 200. In contrast, IC devices not fabricated according to the unique fabrication process flow herein either form a conductive via directly on an epi-layer (as opposed to directly on the source/drain contacts 250, 251, and 253 herein) to achieve back side electrical routing, or may not form these conductive vias at all. Whereas conductive vias formed directly on an epi-layer may have an increased parasitic resistance (e.g., since epi-layers are not as good electrical conductors as metal materials), the metal-to-metal interface formed by the conductive vias 600, 601, and 603 and their respective source/drain contacts 250, 251, and 253 result in a substantially lower resistivity. As such, the IC device 200 of the present disclosure can achieve back side electrical routing at a significantly reduced resistance. The reduced resistance translates into device performance improvements for the IC device 200, including but not limited to: faster speed, lower power consumption, less heat generation, and potentially longer device lifespan.

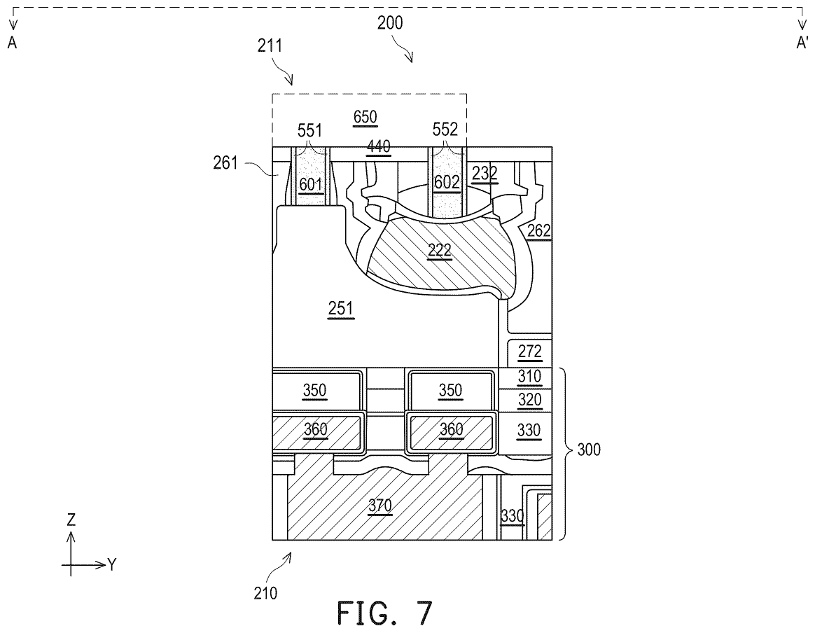

The embodiment of FIG. 6 illustrates a configuration where some of the conductive vias (e.g., conductive vias 600 and 603) of the IC device 200 are formed to vertically extend through semiconductor materials (e.g., the semiconductor materials 230/233 and the source/drain regions 220/223), while some other conductive vias (e.g., conductive via 601) is formed to vertically extend through a dielectric material (e.g., the STI structure 261). However, although such a configuration is fully capable of facilitating back side electrical routing for the IC device 200, it is not intended to be limiting. Other possible configurations are illustrated in the embodiments corresponding to FIGS. 7-9. For reasons of consistency and clarity, similar components in FIGS. 2-6 and FIGS. 7-9 will be labeled the same.

For example, referring to FIG. 7, a diagrammatic fragmentary cross-sectional side view of an embodiment of the IC device 200 is illustrated. In the embodiment illustrated in FIG. 7, the conductive via 601 is still formed to be in direct contact with the back side 211 of the source/drain contact 251. In addition, a conductive via 602 is also formed to extend from the back side 211 toward the front side 210 of the IC device 200. Specifically, the conductive via 602 extends into, and is in direct contact with, the semiconductor material 232. As discussed above, the semiconductor material 232 may be a part of an active region of the IC device 200. In some embodiments, the conductive via 602 may be formed using the same processes that form the conductive via 601. For example, the etching processes 500 discussed above (see FIG. 4) may be used to simultaneously etch the opening 511 (for the conductive via 601) and another opening for the conductive via 602. These openings may be filled by conductive materials using the deposition processes 580 discussed above (see FIG. 6) to form the conductive vias 601 and 602.

Note that the liners 551 are still formed on opposite side surfaces of the conductive via 601 in this embodiment to mitigate the risk of electrical shorting. Likewise, liners 552 are formed on opposite side surfaces of the conductive via 602 to mitigate the risk of electrical shorting between the conductive via 602 and other components of the IC device 200. In addition, a conductive pad 650 is formed over the back side 211 of the IC device 200 to electrically couple the conductive vias 601 and 602 together. That is, a portion of the conductive pad 650 is in direct contact with the back side surface of the conductive via 601, while another portion of the conductive pad 650 is in direct contact with the back side surface of the conductive via 602. As such, the conductive via 602 may be viewed as providing a further electrical path in parallel with the conductive via 601 for the back side electrical routing. Among other things, such a parallel electrical path may offer a reduced total resistance and may tolerate a greater amount of electrical current/voltage in certain IC applications.

Referring now to FIG. 8, a diagrammatic fragmentary cross-sectional side view of another embodiment of the IC device 200 is illustrated. Note that whereas FIGS. 2-7 are Y-cut cross-sectional side views, FIG. 8 is an X-cut cross-sectional side view. For example, the cross-sectional view of FIG. 8 is obtained by taking a cross-sectional cut along a cutline B-B′ (also shown in FIG. 1C). In the embodiment illustrated in FIG. 8, the IC device 200 is a gate-all-around (GAA) device. In more detail, the IC device 200 includes a gate structure 700 that may be an embodiment of the gate structure 140 discussed above with reference to FIG. 1C. The IC device 200 also includes a vertical stack of nano-structures 710 that may be an embodiment of the nano-structures 170 discussed above with reference to FIG. 1C. The nano-structures 710 may include nano-sheets, nano-plates, nano-tubes, nano-wires, etc., and they may serve as the channels of the GAA device. The gate structure 700 circumferentially wraps around each of the nano-structures 710, which is manifested in the cross-sectional side view as portions of the gate structure 700 interleaving with the nano-structures 710 in the vertical Z-direction in FIG. 8.

The IC device 200 further includes a gate via 730 that is located over the front side 210 of the gate structure 700. The gate via 730 is disposed vertically between the gate structure 700 and one of the metal lines 360 of the interconnect structure 300 and extends vertically through an ILD 275, the etching-stop layer 310, and the ILD 320. As such, electrical access to the gate structure 700 can be gained at least in part through the gate via 730. Meanwhile, the IC device 200 also includes source/drain regions 225 and 226 disposed on opposite sides (e.g., in the X-direction) of the gate structure 700. The source/drain regions 225 and 226 are similar to the source/drain regions 220-223 discussed above and may be formed using similar processes (e.g., epitaxial growth). Source/drain contacts 255 and 256 are formed over the front side 210 of the source/drain regions 225 and 226, respectively. The source/drain contacts 255 and 256 protrude into (e.g., protruding toward the back side 211) the source/drain regions 225 and 226, respectively. Electrical access to the source/drain regions 225-226 may also be gained at least in part through the interconnect structure 300. For example, a conductive via 740 may be formed over the front side 210 of the source/drain contact 256. The conductive via 740 is also electrically coupled to the metal line 360. As such, the source/drain contact 256, the conductive via 740, and the metal line 360 collectively provide electrical connectivity to the source/drain region 226.

According to various aspects of the present disclosure, a conductive via 750 is formed over the back side 211 of the source/drain contact 256. The conductive via 750 may be formed using similar processes discussed above (e.g., the processes 500 of FIG. 4 and the processes 580 of FIG. 6) used to form the conductive vias 600-603 of FIG. 6. For example, one or more etching processes may be performed to etch an upside-down-L-shaped opening through the semiconductor material 235 and through the source/drain region 226, such that the source/drain contact 256 is exposed to the back side 211. Thereafter, conductive materials may be deposited to fill such an opening to form the conductive via 750. Note that liners 760 may also be formed on opposite side surfaces of the conductive via 750 in this embodiment as well. The liners 760 may include a dielectric material and may be formed using similar processes that were used to form the liners 550-553 discussed above with reference to FIG. 5.

As shown in FIG. 8, the conductive via 750 may include a segment 750A and a segment 750B. The segment 750A extends vertically through the semiconductor material 235 and partially into the gate structure 700. In other words, the segment 750A is in direct contact with, and electrically connected to, the gate structure 700 from the back side 211. Meanwhile, the segment 750B extends vertically through the source/drain region 226. In other words, the segment 750B is in direct contact with, and electrically connected to, the source/drain contact 256 from the back side 211. The segment 750A is substantially wider than the segment 750B, which results in the upside-down-L like profile for the conductive via 750 in the cross-sectional side view of FIG. 8.

Note that since the conductive via 750 is electrically coupled to both the gate structure 700 and the source/drain contact 256, two parallel electrical paths are created: one electrical path corresponding to the segment 750A of the conductive via 750, the gate structure 700, and the gate via 730, and the other electrical path corresponding to the segment 750B of the conductive via 750, the source/drain contact 256, and the conductive via 740. Among other things, such a parallel electrical path may offer a reduced total resistance and may tolerate a greater amount of electrical current/voltage in certain IC applications.

Referring now to FIG. 9, a diagrammatic fragmentary cross-sectional side view of another embodiment of the IC device 200 is illustrated. Similar to FIG. 8, FIG. 9 is also an X-cut cross-sectional side view, and the IC device 200 is a gate-all-around (GAA) device as well. In the embodiment of FIG. 9, a source/drain contact 258 is implemented to extend vertically through the source/drain region 225 and the ILD 275, and a source/drain contact 259 is implemented to extend vertically through the source/drain region 226 and the ILD 275. Conductive vias 748 and 749 are formed as a part of the interconnect structure 300, where the conductive vias 748 and 749 are electrically coupled to the front side 210 of the source/drain contacts 258 and 259, respectively. The conductive vias 748 and 749 may also be coupled to metal lines of the interconnect structure 300, such as the metal line 360.

According to various aspects of the present disclosure, a conductive via 800 is formed over the back side 211 of the source/drain contact 258. The conductive via 800 may be formed using similar processes discussed above (e.g., the processes 500 of FIG. 4 and the processes 580 of FIG. 6) used to form the conductive vias 600-603 of FIG. 6. For example, one or more etching processes may be performed to etch an opening through the semiconductor material 235 and through the source/drain region 225, such that the source/drain contact 258 is exposed to the back side 211. Thereafter, conductive materials may be deposited to fill such an opening to form the conductive via 800. Note that liners 810 may also be formed on opposite side surfaces of the conductive via 800 in this embodiment as well. The liners 810 may include a dielectric material and may be formed using similar processes that were used to form the liners 550-553 discussed above with reference to FIG. 5. In any case, the fact that the conductive via 800 is formed to be in direct contact with the back side 211 of the source/drain contact 258 means that the embodiment of FIG. 9 can also achieve a reduced resistance, which translates into the device performance improvements discussed above.

FIG. 10 illustrates an integrated circuit fabrication system 900 according to embodiments of the present disclosure, which may be used to fabricate the IC device 200 of the present disclosure. The fabrication system 900 includes a plurality of entities 902, 904, 906, 908, 910, 912, 914, 916 . . . , N that are connected by a communications network 918. The network 918 may be a single network or may be a variety of different networks, such as an intranet and the Internet, and may include both wire line and wireless communication channels.

In an embodiment, the entity 902 represents a service system for manufacturing collaboration; the entity 904 represents an user, such as product engineer monitoring the interested products; the entity 906 represents an engineer, such as a processing engineer to control process and the relevant recipes, or an equipment engineer to monitor or tune the conditions and setting of the processing tools; the entity 908 represents a metrology tool for IC testing and measurement; the entity 910 represents a semiconductor processing tool, such an EUV tool that is used to perform lithography processes to define the various components of the IC device herein; the entity 912 represents a virtual metrology module associated with the processing tool 910; the entity 914 represents an advanced processing control module associated with the processing tool 910 and additionally other processing tools; and the entity 916 represents a sampling module associated with the processing tool 910.

Each entity may interact with other entities and may provide integrated circuit fabrication, processing control, and/or calculating capability to and/or receive such capabilities from the other entities. Each entity may also include one or more computer systems for performing calculations and carrying out automations. For example, the advanced processing control module of the entity 914 may include a plurality of computer hardware having software instructions encoded therein. The computer hardware may include hard drives, flash drives, CD-ROMs, RAM memory, display devices (e.g., monitors), input/output device (e.g., mouse and keyboard). The software instructions may be written in any suitable programming language and may be designed to carry out specific tasks.

The integrated circuit fabrication system 900 enables interaction among the entities for the purpose of integrated circuit (IC) manufacturing, as well as the advanced processing control of the IC manufacturing. In an embodiment, the advanced processing control includes adjusting the processing conditions, settings, and/or recipes of one processing tool applicable to the relevant wafers according to the metrology results.

In another embodiment, the metrology results are measured from a subset of processed wafers according to an optimal sampling rate determined based on the process quality and/or product quality. In yet another embodiment, the metrology results are measured from chosen fields and points of the subset of processed wafers according to an optimal sampling field/point determined based on various characteristics of the process quality and/or product quality.

One of the capabilities provided by the IC fabrication system 900 may enable collaboration and information access in such areas as design, engineering, and processing, metrology, and advanced processing control. Another capability provided by the IC fabrication system 900 may integrate systems between facilities, such as between the metrology tool and the processing tool. Such integration enables facilities to coordinate their activities. For example, integrating the metrology tool and the processing tool may enable manufacturing information to be incorporated more efficiently into the fabrication process, and may enable wafer data from the online or in site measurement with the metrology tool integrated in the associated processing tool.

FIG. 11 is a flowchart illustrating a method 1000 of fabricating a semiconductor device. The method 1000 includes a step 1010 to reduce a thickness of a wafer from a back side. The wafer includes a plurality of source/drain regions and a plurality of source/drain contacts disposed over a front side of the source/drain regions.

The method 1000 includes a step 1020 that is performed after the thickness of the wafer has been reduced, where the step 1020 forms one or more mask layers over the back side of the wafer.

The method 1000 includes a step 1030 to etch one or more openings from the back side of the wafer. The one or more openings expose at least some of the source/drain contacts to the back side.

The method 1000 includes a step 1040 to fill the one or more openings with one or more conductive vias, such that the one or more conductive vias are electrically coupled to the at least some of the source/drain contacts.

In some embodiments, the etching comprises etching at least some of the openings through a semiconductor material or through a shallow trench isolation (STI) structure.

In some embodiments, the etching comprises simultaneously etching a first opening through a semiconductor material and a second opening through a shallow trench isolation (STI) structure. The first opening exposes a first one of the source/drain contacts. The second opening exposes a second one of the source/drain contacts. The first opening is etched to have a substantially deeper depth than the second opening.

In some embodiments, the etching comprises simultaneously etching a first opening through a semiconductor material and a second opening through a shallow trench isolation (STI) structure. The first opening exposes one of the source/drain regions. The second opening exposes one of the source/drain contacts.

In some embodiments, the wafer includes a gate structure. In some embodiments, the etching is performed such that the gate structure is exposed to the back side along with one of the source/drain contacts by a first opening of the one or more openings. In some embodiments, the filling is performed such that a first conductive via of the one or more conductive vias filling the first opening is electrically coupled to the gate structure and the one of the source/drain contacts simultaneously.

It is understood that the method 1000 may include further steps performed before, during, or after the steps 1010-1040. For example, the method 1000 may include a step that is performed after the one or more openings have been etched but before the one or more conductive vias have been formed, where electrically insulating liners are formed on sidewalls of the one or more openings. Other steps may include formation of additional metallization features, packaging, and wafer acceptance testing, etc. For reasons of simplicity, these additional steps are not discussed in detail herein.

In summary, the present disclosure forms conductive vias directly on the back side of source/drain contacts. In more detail, source/drain contacts may be formed on the front side of source/drain regions (which may be epi-layers). Thereafter, openings may be etched from the back side to expose the source/drain contacts to the back side. Conductive materials are then deposited into the openings to form the conductive contacts, which are in direct contact with the back side of the source/drain contacts. By implementing the conductive vias in this manner, the embodiments of the present disclosure offer advantages over conventional devices. It is understood, however, that no particular advantage is required, other embodiments may offer different advantages, and that not all advantages are necessarily disclosed herein. One advantage is improved device performance. For example, by forming the conductive vias to be in direct contact with the source/drain contacts, the IC device of the present can achieve a substantially lower resistance compared to other IC devices where vias are formed on epi-layers. This is because a metal-to-metal interface (e.g., the interface between the conductive via and the source/drain contact) of the present disclosure has substantially lower resistance than a metal-to-epilayer interface (e.g., the interface in IC devices where the conductive via is formed on the epi-layer). A reduced resistance can translate into faster device speed, reduced power consumption, less heat generation, and potentially longer device lifespan. Yield may also be increased as a result, which may be reflected in a wafer acceptance test performance. Other advantages may include ease of fabrication and compatibility with existing fabrication processes.

The advanced lithography process, method, and materials described above can be used in many applications, including in IC devices using fin-type field effect transistors (FinFETs). For example, the fins may be patterned to produce a relatively close spacing between features, for which the above disclosure is well suited. In addition, spacers used in forming fins of FinFETs, also referred to as mandrels, can be processed according to the above disclosure. It is also understood that the various aspects of the present disclosure discussed above may apply to multi-channel devices such as Gate-All-Around (GAA) devices. To the extent that the present disclosure refers to a fin structure or FinFET devices, such discussions may apply equally to the GAA devices.

One aspect of the present disclosure pertains to a semiconductor device. The semiconductor device includes a plurality of source/drain regions. The semiconductor device includes a plurality of source/drain contacts disposed over a front side of the plurality of source/drain regions, respectively. The plurality of the source/drain contacts are electrically coupled to the plurality of source/drain regions. The semiconductor device includes a plurality of conductive vias disposed over a back side of the source/drain contacts, respectively. The back side is opposite the front side. The plurality of the conductive vias are electrically coupled to the plurality of source/drain contacts.

Another aspect of the present disclosure pertains to a semiconductor device. The semiconductor device includes a semiconductor substrate. The semiconductor device includes a gate structure located over a first side of the semiconductor substrate in a cross-sectional side view. The semiconductor device a first epi-layer and a second epi-layer each located over the first side of the semiconductor substrate in the cross-sectional side view. The gate structure is located between the first epi-layer and the second epi-layer in the cross-sectional side view. The semiconductor device includes a first conductive contact and a second conductive contact located over the first side of the first epi-layer and the second epi-layer, respectively. The first conductive contact protrudes into the first epi-layer in the cross-sectional side view. The second conductive contact protrudes into the second epi-layer in the cross-sectional side view. The semiconductor device includes a conductive via located over a second side of the gate structure. The second side is opposite the first side. A first segment of the conductive via extends vertically through the semiconductor substrate and protrudes into the gate structure. A second segment of the conductive via extends vertically through the second epi-layer and is in direct contact with the second conductive contact.

Another aspect of the present disclosure pertains to a method of fabricating a semiconductor device. A thickness of a wafer is reduced from a back side. The wafer includes a plurality of source/drain regions and a plurality of source/drain contacts disposed over a front side of the source/drain regions. After the thickness of the wafer has been reduced, one or more mask layers is formed over the back side of the wafer. One or more openings are etched from the back side of the wafer. The one or more openings expose at least some of the source/drain contacts to the back side. The one or more openings are filled with one or more conductive vias, such that the one or more conductive vias are electrically coupled to the at least some of the source/drain contacts.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A device, comprising:
a plurality of source/drain regions;
a plurality of source/drain contacts disposed over a front side of the plurality of source/drain regions, respectively, wherein the plurality of the source/drain contacts are electrically coupled to the plurality of source/drain regions; and
a plurality of conductive vias disposed over a back side of the source/drain contacts, respectively, wherein the back side is opposite the front side, and wherein the plurality of the conductive vias are electrically coupled to the plurality of source/drain contacts.

2. The device of claim 1, further comprising an interconnect structure disposed over the front side of the source/drain contacts.

3. The device of claim 1, wherein at least one of the conductive vias extends vertically through a semiconductor material.

4. The device of claim 1, wherein at least one of the conductive vias extends vertically through a shallow trench isolation (STI) structure.

5. The device of claim 4, wherein the at least one of the conductive vias is a first conductive via, wherein the device further comprises a second conductive via that is disposed over the back side of one of the source/drain regions;
wherein:
the second conductive via is electrically coupled to the one of the source/drain regions; and
the first conductive via and the second conductive via are electrically coupled together.

6. The device of claim 1, wherein:
a first conductive via of the conductive vias extends vertically through a semiconductor material and is electrically coupled to a first source/drain contact of the source/drain contacts; and
a second conductive via of the conductive vias extends vertically through a shallow trench isolation (STI) structure and is electrically coupled to a second source/drain contact of the source/drain contacts.

7. The device of claim 6, wherein the first conductive via is substantially longer than the second conductive via.

8. The device of claim 1, further comprising a gate structure, wherein at least one of the conductive vias is electrically coupled to both the gate structure and one of the source/drain contacts.

9. The device of claim 8, wherein at least one of the conductive vias has a cross-sectional side view profile that resembles a letter “L”.

10. The device of claim 1, wherein the device comprises a gate-all-around (GAA) transistor.

11. A device, comprising:
a semiconductor substrate;
a gate structure located over a first side of the semiconductor substrate in a cross-sectional side view;
a first epi-layer and a second epi-layer each located over the first side of the semiconductor substrate in the cross-sectional side view, wherein the gate structure is located between the first epi-layer and the second epi-layer in the cross-sectional side view;
a first conductive contact and a second conductive contact located over the first side of the first epi-layer and the second epi-layer, respectively, wherein the first conductive contact protrudes into the first epi-layer in the cross-sectional side view, and wherein the second conductive contact protrudes into the second epi-layer in the cross-sectional side view; and
a conductive via located over a second side of the gate structure, the second side being opposite the first side, wherein a first segment of the conductive via extends vertically through the semiconductor substrate and protrudes into the gate structure, and wherein a second segment of the conductive via extends vertically through the second epi-layer and is in direct contact with the second conductive contact.

12. The device of claim 11, wherein the gate structure is a gate structure of a gate-all-around (GAA) transistor.

13. The device of claim 11, further comprising an interconnect structure located over the first side of the gate structure, the first conductive contact, and the second conductive contact.

14. A method, comprising:
reducing a thickness of a wafer from a back side, wherein the wafer includes a plurality of source/drain regions and a plurality of source/drain contacts disposed over a front side of the source/drain regions;
after the thickness of the wafer has been reduced, forming one or more mask layers over the back side of the wafer;
etching one or more openings from the back side of the wafer, wherein the one or more openings expose at least some of the source/drain contacts to the back side; and
filling the one or more openings with one or more conductive vias, such that the one or more conductive vias are electrically coupled to the at least some of the source/drain contacts.

15. The method of claim 14, further comprising: after the one or more openings have been etched but before the one or more conductive vias have been formed, forming electrically insulating liners on sidewalls of the one or more openings.

16. The method of claim 14, wherein the etching comprises etching at least some of the openings through a semiconductor material or through a shallow trench isolation (STI) structure.

17. The method of claim 14, wherein:
the etching comprises simultaneously etching a first opening through a semiconductor material and a second opening through a shallow trench isolation (STI) structure;
the first opening exposes a first one of the source/drain contacts; and
the second opening exposes a second one of the source/drain contacts.

18. The method of claim 17, wherein the first opening is etched to have a substantially deeper depth than the second opening.

19. The method of claim 14, wherein:
the etching comprises simultaneously etching a first opening through a semiconductor material and a second opening through a shallow trench isolation (STI) structure;
the first opening exposes one of the source/drain regions; and
the second opening exposes one of the source/drain contacts.

20. The method of claim 14, wherein:
the wafer includes a gate structure;
the etching is performed such that the gate structure is exposed to the back side along with one of the source/drain contacts by a first opening of the one or more openings; and
the filling is performed such that a first conductive via of the one or more conductive vias filling the first opening is electrically coupled to the gate structure and the one of the source/drain contacts simultaneously.
